(19) United States
(12) Patent Application Publication
(10) Pub. No.: US 2010/0075857 A1
(43) Pub. Date: Mar. 25, 2010

(54) SUPERCONDUCTING TAPE AND PRODUCTION METHOD THEREOF

(75) Inventor: Naoki Ayai, Osaka-shi (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi, Osaka (JP)

(21) Appl. No.: 12/445,145

(22) PCT Filed: May 8, 2008
(86) PCT No.: PCT/JP2008/058522

§ 371 Date: Apr. 10, 2009

(30) Foreign Application Priority Data
Aug. 14, 2007 (JP) 2007-211245

(51) Int. Cl. H01B 12/06; H01L 39/24

(52) U.S. Cl. 505/230; 505/434; 174/125.1; 427/62

(57) ABSTRACT

The invention offers a superconducting tape that maintains both high allowable tension and low splice resistance and a method of producing the superconducting tape. The superconducting tape is provided with a main-body portion and a reinforcement portion. The main-body portion has the shape of a tape and has a superconductor. The reinforcement portion is composed of precipitation-hardened-type copper alloy or alloy of tin and copper and is formed on at least one surface side of the main-body portion.

### TECHNICAL FIELD

The present invention relates to a superconducting tape and a production method thereof, for example, to a superconducting tape that has high allowable tension and low splice resistance and a production method thereof.

### BACKGROUND ART

There is a tape-shaped superconducting wire (a superconducting tape) that is composed of a multifilament wire having a structure in which oxide superconductors having, for example, a Bi2223 phase and another phase are covered with a sheath portion made of silver or the like. The superconducting tape can be used at the liquid-nitrogen temperature, can have a relatively high critical-current density, and can be relatively easily produced at a long length. Consequently, the superconducting tape has been expected to be applied to a superconducting coil or a superconducting magnet.

For example, when a superconducting coil is produced, a superconducting tape is wound in the shape of a coil. At this moment, the superconducting tape is subjected to a high tension (a bending stress). Consequently, the superconducting tape is required to have a high allowable tension, which is the maximum tension that can maintain the performance of the superconductor. In the superconducting tape, the sheath portion plays a role of securing the allowable tension and a role of giving a flexibility to the superconductor, which is made of ceramic.

On the other hand, the sheath portion also plays a role of having a good electrical contact with the superconductor. This condition prevents the free selection of the material of the sheath portion. As a result, there has been a limitation in increasing the allowable tension of the superconducting tape. In view of the above circumstances, the specification of the U.S. Pat. No. 5,801,124 (Patent literature 1) and the specification of the U.S. Pat. No. 6,649,280 (Patent literature 2), for example, have disclosed techniques that can increase the mechanical strength of the superconducting tape. Patent literatures 1 and 2 have disclosed a structure in which a thin stainless-steel plate is bonded to one or each of the two main surfaces of the superconducting tape using solder.

Patent literature 1: the specification of the U.S. Pat. No. 5,801,124

Patent literature 2: the specification of the U.S. Pat. No. 6,649,280

### DISCLOSURE OF THE INVENTION

### Problem to be Solved by the Invention

The superconducting tape disclosed in Patent literatures 1 and 2, however, has a problem in that when superconducting tapes are spliced together to obtain a longer superconducting tape, the resistance at the place where the thin stainless-steel plates bonded to the superconducting tapes are spliced together (the splice resistance) becomes high. To decrease the splice resistance, a method is conceivable in which, first, the solder bonding between the thin stainless-steel plate and the superconducting tape is removed at the splicing position of the two superconducting tapes and, then, the superconducting tapes are spliced together directly. However, when this method is employed, the operation to perform splicing becomes complicated. As a result, this method has problems in that the possibility to deteriorate the superconducting tape is high and the strength at the spliced portion is decreased. Therefore, it has been difficult to splice the superconducting tapes together.

Furthermore, when a thin plate of solid-solution-hardened-type copper alloy, such as brass, is used, which has lower splice resistance than that of the thin stainless-steel plate, the use of this plate has a problem in that the superconducting tape provided with this plate has a lower allowable tension than that of the superconducting tape provided with the thin stainless-steel plate, because the solid-solution-hardened-type copper alloy has a lower mechanical strength than that of the stainless steel. Consequently, when the superconducting tape provided with a thin plate of solid-solution-hardened-type copper alloy is required to have an allowable tension comparable to that of the superconducting tape provided with the thin stainless-steel plate, it is necessary to increase the thickness of the thin plate of solid-solution-hardened-type copper alloy. However, when the thickness of the thin plate of solid-solution-hardened-type copper alloy is increased, not only is the splice resistance increased but also the critical-current density per cross-sectional area including the thin plate of solid-solution-hardened-type copper alloy is decreased.

In view of the above circumstances, an object of the present invention is to offer a superconducting tape that maintains both high allowable tension and low splice resistance and a method of producing the superconducting tape.

### Means to Solve the Problem

The superconducting tape of the present invention is provided with a main-body portion that has the shape of a tape and that has a superconductor and a reinforcement portion that is composed of precipitation-hardened-type copper alloy or alloy of tin (Sn) and copper (Cu) and that is formed on at least one surface side of the main-body portion.

The method of the present invention for producing a superconducting tape is provided with a step of preparing a main-body portion that has the shape of a tape and that has a superconductor and a step of forming a reinforcement portion that is composed of precipitation-hardened-type copper alloy or alloy of tin and copper and that is positioned on at least one surface side of the main-body portion.

The present inventor diligently studied on a material that can maintain high allowable tension and low splice resistance when used as a reinforcement portion formed on the surface of the main-body portion that has the shape of a tape and that has a superconductor. As a result, the present inventor found the use of precipitation-hardened-type copper alloy or alloy of tin and copper. Precipitation-hardened-type copper alloy and alloy of tin and copper not only have a mechanical strength close to that of stainless steel but also have a resistivity lower than that of stainless steel by about two digits at a cryogenic environment in which a superconducting tape is used. Consequently, according to the superconducting tape and the method of producing the superconducting tape both of the present invention, not only high allowable tension but also low splice resistance can be maintained. In addition, because high allowable tension can be maintained, the thickness of the reinforcement portion can be decreased. Therefore, the decrease in critical-current density can be suppressed.

In the above-described superconducting tape, it is desirable that the precipitation-hardened-type copper alloy be composed of alloy of copper and at least one material selected from the group consisting of silver (Ag), chromium (Cr), and zirconium (Zr).

In the above-described method of producing a superconducting tape, it is desirable that the step of forming a reinforcement portion include a step of preparing the reinforcement portion composed of the precipitation-hardened-type copper alloy that is composed of alloy of copper and at least one material selected from the group consisting of silver, chromium, and zirconium.

Because the alloy of copper and at least one material selected from the group consisting of silver, chromium, and zirconium has particularly low resistivity, the splice resistance can be decreased.

In the foregoing superconducting tape, it is desirable that the superconducting tape be further provided with a solder layer formed between the main-body portion and the reinforcement portion.

In the foregoing method of producing a superconducting tape, it is desirable that the method be further provided with a step of forming a solder layer between the main-body portion and the reinforcement portion.

The providing of the solder layer enables securer bonding between the main-body portion and the reinforcement portion. A solder layer usually used to bond a thin stainless-steel plate to the superconducting tape contains strongly acidic flux. In contrast to this, the solder layer to be used to bond the reinforcement portion of the present invention composed of precipitation-hardened-type copper alloy or alloy of tin and copper to the main-body portion can bond the reinforcement portion to the main-body portion even without containing strongly acidic flux. Consequently, even in the case where the reinforcement portion is bonded to the main-body portion using the solder layer, there exists no strongly acidic flux that remains after the bonding. As a result, the method of the present invention can prevent the occurrence of corrosion at the inside of the superconducting tape with the passage of time. In addition, the method can prevent the occurrence of corrosion in the equipment for producing the superconducting tape.

In this specification, the term “precipitation-hardened-type copper alloy” means a copper alloy having an increased strength obtained by precipitating, through an aging treatment, either an added element or an intermetallic compound composed of the added element and copper. The foregoing alloy is advantageous in that it can have high strength and low resistivity. The term “solid-solution-hardened-type copper alloy” means a copper alloy having a state in which the added element forms a solid solution with copper. The types of the solid-solution-hardened-type copper alloy include brass, which is an alloy of copper and zinc.

### EFFECT OF THE INVENTION

According to the superconducting tape and the method of producing the superconducting tape both of the present invention, the superconducting tape can maintain not only high allowable tension but also low splice resistance.

### BRIEF DESCRIPTION OF THE DRAWINGS

FIG. 1 is a partly cross-sectional perspective view schematically showing the structure of the superconducting tape in Embodiment 1 of the present invention.

FIG. 2 is a flow chart showing the method of producing the superconducting tape in Embodiment 1 of the present invention.

FIG. 3 is a partly cross-sectional perspective view schematically showing the structure of the superconducting tape in Embodiment 2 of the present invention.

FIG. 4 is a flow chart showing the method of producing the superconducting tape in Embodiment 2 of the present invention.

FIG. 5 is a partly cross-sectional perspective view schematically showing the structure of the superconducting tape in Embodiment 3 of the present invention.

FIG. 6 is a partly cross-sectional perspective view schematically showing the structure of the superconducting tape in Embodiment 4 of the present invention.

FIG. 7 is a partly cross-sectional perspective view schematically showing the structure of the superconducting tape in Embodiment 5 of the present invention.

FIG. 8 is a cross-sectional view for explaining the method of measuring the splice resistance in Example.

### EXPLANATION OF THE SIGN

1a, 1b, 1c, 1d, and 1e: Superconducting tape; 3: Superconductor; 3a and 7a: Top surface; 4: Buffer layer; 5: Sheath portion; 6: Substrate; 6b and 7b: Undersurface; 7: Main-body portion; 9: Reinforcement portion; 11: Solder layer; x: Lap.

### BEST MODE FOR CARRYING OUT THE INVENTION

Embodiments of the present invention are explained below based on the drawing. In the following drawing, the same reference sign is given to the same or corresponding portion to eliminate duplicated explanations.

### Embodiment 1

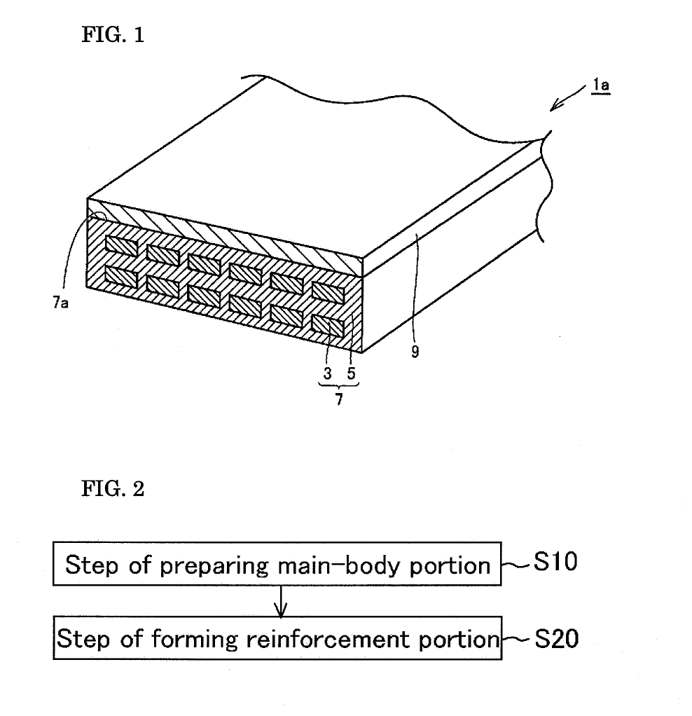

FIG. 1 is a partly cross-sectional perspective view schematically showing the structure of the superconducting tape in Embodiment 1 of the present invention. As shown in FIG. 1, a superconducting tape 1a in this embodiment is provided with a main-body portion 7 and a reinforcement portion 9. The reinforcement portion 9 is placed on the side of a top surface 7a of the main-body portion 7 so as to be positioned along the length of the main-body portion 7.

The main-body portion 7 has the shape of a tape and has a plurality of superconductors 3 that extend longitudinally and a sheath portion 5 that covers the entire circumferences of the multiple superconductors 3. The sheath portion 5 is in contact with the superconductors 3. It is desirable that each of the multiple superconductors 3 be a bismuth-based superconductor having, for example, a Bi—Pb—Sr—Ca—Cu—O-based composition. In particular, it is most desirable to use a material including a Bi2223 phase, in which the atomic ratio of (bismuth and lead):strontium:calcium:copper is approximately expressed as a ratio of about 2:2:2:3. The material of the sheath portion 5 is composed of, for example, silver or silver alloy.

The reinforcement portion 9 is composed of precipitation-hardened-type copper alloy or alloy of tin and copper. The types of precipitation-hardened-type copper alloy include copper-beryllium alloy, copper-chromium alloy, copper-titanium alloy, copper-zirconium alloy, copper-chromium-titanium alloy, copper-chromium-zirconium alloy, and copper-chromium-zirconium-titanium alloy. Because low resistivity can be achieved at a cryogenic temperature not higher than the liquid-nitrogen temperature and because a resistance to heat can be achieved that prevents the strength from decreasing by the heat at the time the superconducting tapes 1a are spliced together using solder, it is desirable that the reinforcement portion 9 be composed of alloy of copper and at least one material selected from the group consisting of silver, chromium, tin, and zirconium, more desirably alloy of tin and copper, silver-added copper, copper-chromium alloy, copper-zirconium alloy, or copper-chromium-zirconium alloy.

Having a higher mechanical strength than that of the main-body portion 7, the reinforcement portion 9 plays a role of increasing the mechanical strength of the superconducting tape 1a to maintain a high allowable tension.

In the above description, an explanation is given to a structure in which the main-body portion 7 has the multiple superconductors 3 (a multifilament wire). Nevertheless, another structure may be employed in which the main-body portion 7 has only a single superconductor (a single-filament wire).

An example of concrete dimensions of the superconducting tape 1a is given below. The reinforcement portion 9 has a thickness (the vertical dimension in FIG. 1) of 0.02 mm and a width (the lateral dimension in FIG. 1) of 4.3 mm. The main-body portion 7 has a thickness of 0.22 mm and a width of 4.2 mm.

FIG. 2 is a flow chart showing the method of producing the superconducting tape in Embodiment 1 of the present invention. The method of producing the superconducting tape 1a in this embodiment is explained below by using FIGS. 1 and 2.

As shown in FIGS. 1 and 2, first, the main-body portion 7 that has the shape of a tape and that has the superconductors 3 is prepared (Step S10). More specifically, material powders of oxide or carbonate are mixed so that Bi, Pb, Sr, Ca, and Cu can have a specified composition ratio. The mixed powder is subjected to a repeated processing of heat treatment and pulverization. This process produces a precursor powder composed of a Bi2223 phase, a Bi2212 phase, and a nonsuperconducting phase. Next, the precursor powder is filled into a metal tube. Subsequently, the metal tube filled with the precursor powder is processed by drawing. In this process, the drawing operation and an intermediate annealing treatment are repeated. Thus, a cladded wire is produced in which a precursor filament as the core is covered with a metal tube. Next, a plurality of cladded wires are bundled together to be inserted into another metal tube again without clearance. This operation produces a multifilament wire having, for example, 55 filaments. The multifilament wire is processed by drawing. The drawing process produces a wire having a form in which the sheath portion 5 covers precursor powders of oxide superconductors including the Bi2223 phase. The multifilament wire is subjected to a repeated processing of a plurality of times of rolling operation and heat treatment. The heat treatment is performed in an oxygen-containing atmosphere having an oxygen partial pressure of 0.01 MPa or less. Through this process, the precursor powders are transformed into the superconductors 3. The rolling operation transforms the wire into the shape of a tape. The above-described step forms the main-body portion 7 that has the shape of a tape and that has both the superconductors 3 and the sheath portion 5 covering the entire circumferences of the superconductors 3.

Next, a reinforcement portion composed of precipitation-hardened-type copper alloy or alloy of tin and copper is formed on at least one surface side of the main-body portion 7 (Step S20). More specifically, first, the plate-shaped reinforcement portion 9 is prepared that is composed of precipitation-hardened-type copper alloy or alloy of tin and copper. Then, the reinforcement portion 9 is placed on the side of a top surface 7a of the main-body portion 7 so as to be bonded to the main-body portion 7. The method of bonding the reinforcement portion 9 to the main-body portion 7 has no particular limitation. A commonly known method, such as the application of heat or pressure, may be employed. The above-described steps (Steps S10 and S20) can produce the superconducting tape 1a shown in FIG. 1.

It is desirable that the step of forming the reinforcement portion 9 (Step S20) include a step of preparing the reinforcement portion 9 composed of alloy of copper and at least one material selected from the group consisting of silver, chromium, tin, and zirconium.

As explained above, the superconducting tape 1a in this embodiment is provided with the main-body portion 7 that has the shape of a tape and that has both superconductors 3 and the reinforcement portion 9 that is composed of precipitation-hardened-type copper alloy or alloy of tin and copper and that is formed on at least one surface side of the main-body portion 7.

The method of producing the superconducting tape 1a in this embodiment has both a step (S10) of preparing the main-body portion 7 that has the shape of a tape and that has superconductors 3 and a step (S20) of forming, on at least one surface side of the main-body portion 7, the reinforcement portion 9 composed of precipitation-hardened-type copper alloy or alloy of tin and copper.

According to the superconducting tape 1a and the production method thereof both in this embodiment, because the precipitation-hardened-type copper alloy and the alloy of tin and copper have a mechanical strength comparable to that of stainless steel, a high allowable tension can be maintained by forming on the main-body portion 7 the reinforcement portion 9 composed of precipitation-hardened-type copper alloy or alloy of tin and copper. Consequently, it is not necessary to increase the thickness of the reinforcement portion 9 in order to achieve a required allowable tension. As a result, the decrease in the critical-current density of the superconducting tape 1a can be suppressed. Moreover, the precipitation-hardened-type copper alloy and the alloy of tin and copper have an electric conductivity higher than that of stainless steel. Therefore, when the reinforcement portions 9 are spliced with one another in a plurality of superconducting tapes 1a, low splice resistance can be maintained.

### Embodiment 2

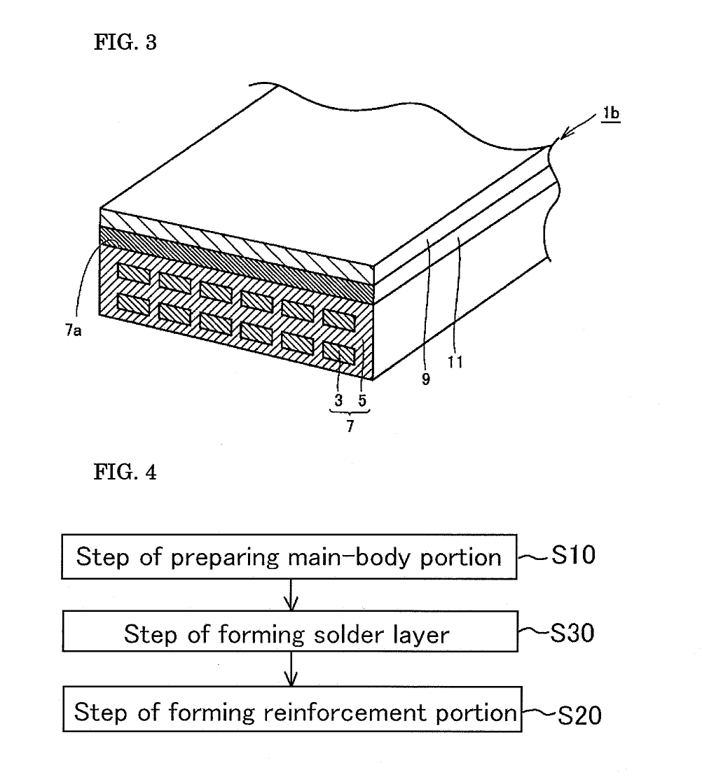

FIG. 3 is a partly cross-sectional perspective view schematically showing the structure of the superconducting tape in Embodiment 2 of the present invention. As shown in FIG. 3, a superconducting tape 1b in this embodiment has basically the same structure as that of the superconducting tape 1a in Embodiment 1, except that the tape 1b is further provided with a solder layer 11 formed between the main-body portion 7 and the reinforcement portion 9.

The material of the solder layer 11 has no particular limitation providing that it can bond the main-body portion 7 with the reinforcement portion 9. For example, commonly known solder may be used, such as Sn—Pb (lead) eutectic solder and Sn—Cu-based or Sn—Ag—Cu-based Pb-free solder. The solder layer 11 has a thickness of, for example, 2.0 to 5.0 μm.

FIG. 4 is a flow chart showing the method of producing the superconducting tape in Embodiment 2 of the present invention. The method of producing the superconducting tape 1b in this embodiment is explained below by using FIGS. 3 and 4.

As shown in FIGS. 3 and 4, first, the main-body portion 7 that has the shape of a tape and that has the superconductors 3 is prepared (Step S10). Because Step S10 is the same as that of Embodiment 1, the explanation for the step is omitted.

Next, the solder layer 11 is formed (Step S30). More specifically, the solder layer 11 is formed on the main-body portion 7 using, for example, the metal-plating method or the vapor deposition method.

Step S30 is not limited to the step of forming the solder layer 11 on the main-body portion 7. For example, by preparing the reinforcement portion 9 in advance, the solder layer 11 may be formed on the reinforcement portion 9's surface that is to face the main-body portion 7. Alternatively, a layer to form the solder layer 11 may be formed on each of the main-body portion 7's surface that is to face the reinforcement portion 9 and the reinforcement portion 9's surface that is to face the main-body portion 7.

Next, the reinforcement portion 9 is formed (Step S20). More specifically, for example, by applying heat to the solder layer 11 formed on the main-body portion 7 or the reinforcement portion 9 and then by hardening it, the main-body portion 7 and the reinforcement portion 9 are bonded together.

Steps S20 and S30 are not particularly limited to the above-described methods. It is desirable to perform the above-described steps S20 and S30 practically simultaneously. More specifically, first, the main-body portion 7 and the reinforcement portion 9 are passed through a molten-solder bath in which the material of the solder layer 11 is melted. Subsequently, they are passed through a gathering die to unify them. Thus, the main-body portion 7 and the reinforcement portion 9 are bonded together through the solder layer 11. In this case, the main-body portion 7 and the reinforcement portion 9 are plated with the solder layer 11 at their other surfaces than the surface for the bonding. As a result, their corrosion resistance is improved and the splicing at the ends using solder becomes easier.

In the above-described step S30, flux may be used together with the solder layer 11. More specifically, for example, before introducing the main-body portion 7 and the reinforcement portion 9 into the molten-solder bath, they are passed through a flux bath to activate the surface of the reinforcement portion 9. It is desirable that the flux be made of material that improve the bonding property between the solder and the reinforcement portion 9. In addition, to avoid the adverse effect on the sheath portion 5 and the production equipment, it is desirable to use mildly acidic flux. The types of mildly acidic flux include organic-acid-based flux and resin-based flux.

As explained above, the superconducting tape 1b in this embodiment is further provided with the solder layer 11 formed between the main-body portion 7 and the reinforcement portion 9. The method of producing the superconducting tape 1b in this embodiment further has a step (Step S30) of forming the solder layer 11 between the main-body portion 7 and the reinforcement portion 9. The solder layer 11 enables securer bonding between the main-body portion 7 and the reinforcement portion 9.

A solder layer usually used to bond a thin stainless-steel plate to the superconducting tape contains the residue of strongly acidic flux. The reason is explained below. Chromium contained in stainless steel bonds with oxygen in the air to produce chromium oxide. A passive film of the chromium oxide is formed on the surface of the stainless steel. The passive film of the chromium oxide has poor wettability with the solder layer. As a result, it was unable to attain easy bonding between the superconducting tape and the stainless steel. To achieve easy production of a superconducting tape bonded with a thin stainless-steel tape, the use of strongly acidic flux can remove the passive film of the chromium oxide. However, this method has a problem in that residual flux after the bonding causes corrosion of the main-body portion of the superconducting tape with the passage of time. The flux remaining at the inside of the bonded portion cannot be removed by the washing from outside after the bonding.

On the other hand, the reinforcement portion 9 in this embodiment composed of precipitation-hardened-type copper alloy or alloy of tin and copper does not form a sturdy passive film, which appears on stainless steel. Consequently, it is not necessary to use strongly acidic flux at the time the bonding is performed by using the solder layer 11. Therefore, the solder layer 11 used for the bonding between the reinforcement portion 9 and the main-body portion 7 can remove the passive film formed on the surface of the precipitation-hardened-type copper alloy or alloy of tin and copper even without containing strongly acidic flux. As a result, even when the reinforcement portion 9 and the main-body portion 7 are bonded together using the solder layer 11, there exists no strongly acidic flux that remains after the bonding. This method can prevent the occurrence of corrosion at the sheath portion 5 with the passage of time. This method can also prevent the occurrence of corrosion in the equipment for producing the superconducting tape 1b.

### Embodiment 3

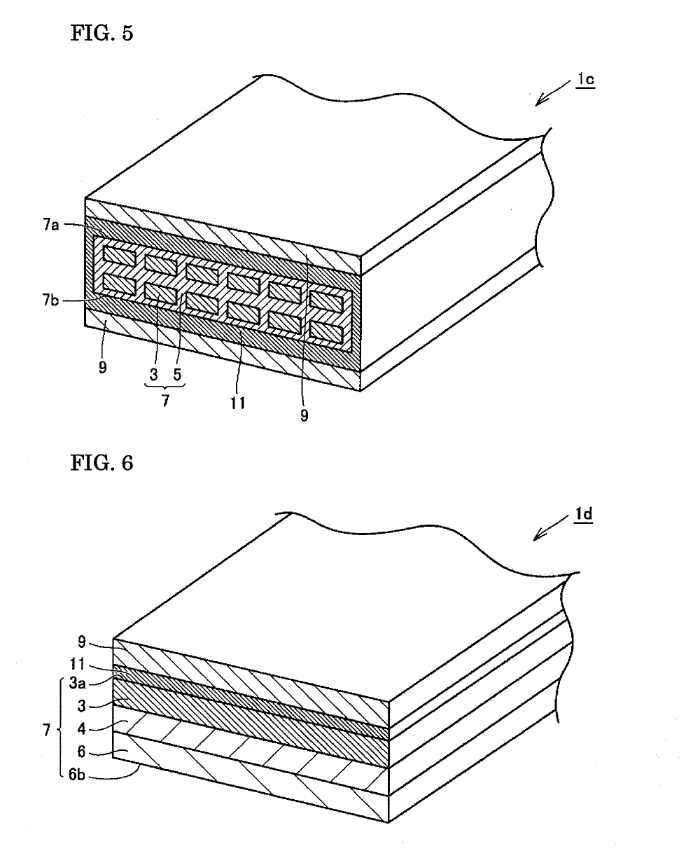

FIG. 5 is a partly cross-sectional perspective view schematically showing the structure of the superconducting tape in Embodiment 3 of the present invention. As shown in FIG. 5, a superconducting tape 1b in this embodiment has basically the same structure as that of the superconducting tape 1a in Embodiment 1, except that the tape 1b is further provided with a solder layer 11 formed so as to cover the entire circumference of the main-body portion 7 and with another reinforcement portion 9 placed on the side of the undersurface 7b of the main-body portion 7.

The method of producing the superconducting tape 1c in this embodiment is basically the same as that of producing the superconducting tape 1b in Embodiment 2, except that the solder layer 11 is formed so as to cover the entire circumference of the main-body portion 7 in Step S30 of forming the solder layer 11.

More specifically, in Step S30 of forming the solder layer 11, the solder layer 11 is formed so as to cover the entire circumference of the main-body portion 7.

This embodiment shows the case where the solder layer 11 is formed on the entire circumference of the main-body portion 7. Nevertheless, because the reinforcement portion 9 is placed on the side of the top surface 7a and on the side of the undersurface 7b of the main-body portion 7, the solder layer 11 needs only to be formed at least on the top surface 7a and on the undersurface 7b of the main-body portion 7.

As explained above, according to the superconducting tape 1c and the production method thereof both in this embodiment, the solder layer 11 is formed on the entire circumference of the main-body portion 7 and the reinforcement portion 9 is placed on the side of the top surface 7a and on the side of the undersurface 7b of the main-body portion 7. By placing the reinforcement portion 9 on the side of the top surface 7a and on the side of the undersurface 7b of the main-body portion 7, the mechanical strength of the superconducting tape 1c is further increased. As a result, the allowable tension can be increased.

### Embodiment 4

FIG. 6 is a partly cross-sectional perspective view schematically showing the structure of the superconducting tape in Embodiment 4 of the present invention. As shown in FIG. 6, a superconducting tape 1b in this embodiment has basically the same structure as that of the superconducting tape 1b in Embodiment 2, except that the tape 1b has a main-body portion 7 composed of a thin-film superconducting tape.

As shown in FIG. 6, the main-body portion 7 in this embodiment has layers composed of a substrate 6, a buffer layer 4 placed directly on the substrate 6, and a superconductor 3 placed directly on the buffer layer 4.

The substrate 6 is made of metal such as stainless steel, nickel alloy (for example, Hastelloy), or silver alloy. The buffer layer is made of, for example, yttrium-stabilized zirconia, cerium oxide, magnesium oxide, or strontium titanate. In spite of the above description, the buffer layer 4 may be omitted.

The superconductor 3 is composed of an RE123-based superconductor, for example. The term “an RE123-based superconductor” means a superconductor that satisfies the conditions 0.7≦x≦1.3, 1.7≦y≦2.3, and 2.7≦z≦3.3 in the molecular formula REₓBa_{y}Cu_{z}O_{7-d}. The term “RE” in the RE123-based superconductor means a material that contains a rare-earth element, the element yttrium, or both. The types of rare-earth elements include neodymium (Nd), gadolinium (Gd), holmium (Ho), and samarium (Sm). The RE123-based superconducting wire is advantageous in that it has a higher critical-current density than that of a bismuth-based superconducting wire at the liquid-nitrogen temperature (77.3 K). It is also advantageous in that it has a higher critical-current value than that of a bismuth-based superconducting wire at the same cryogenic temperature and magnetic field. On the other hand, whereas a bismuth-based superconductor can be covered with a sheath portion, the RE123-based superconductor cannot be covered with it. Consequently, the RE123-based superconductor is produced by a method in which the film of a superconductor (a thin-film superconducting material) is deposited on a textured metal substrate through only the gas-phase method or only the liquid-phase method.

The main-body portion 7 may further be provided with a stabilizing layer (not shown) on the layer composed of the superconductor 3. The stabilizing layer is provided to protect the surface of the superconductor 3 and is made of, for example, silver or copper.

A reinforcement portion 9 is provided on the side of the top surface 3a of the layer composed of the superconductor 3 through a solder layer 11. Consequently, the reinforcement portion 9 composed of precipitation-hardened-type copper alloy or alloy of tin and copper can have a good electric connection with the layer composed of the superconductor 3. The reinforcement portion 9 may be provided on the side of the undersurface 6b of the substrate 6.

The method of producing the superconducting tape 1d in this embodiment is basically the same as that of producing the superconducting tape 1b in Embodiment 2, except in the step of preparing the main-body portion (Step S10).

More specifically, first, the substrate 6 is prepared. Subsequently, the buffer layer 4 is formed on the substrate 6 through, for example, the vapor deposition method. Next, the layer composed of the superconductor 3 is formed on the buffer layer 4 through, for example, the vapor deposition method.

As explained above, according to the superconducting tape 1d and the production method thereof both in this embodiment, the main-body portion 7 is formed by using a thin-film superconducting tape. The superconducting tape 1d provided with the main-body portion 7 formed by using a thin-film superconducting tape is also provided with the reinforcement portion 9 composed of precipitation-hardened-type copper alloy or alloy of tin and copper. Consequently, as with the superconducting tapes in the other embodiments, the superconducting tape 1d has an effect of maintaining high allowable tension and low splice resistance. The superconductor 3 constituting a part of the main-body portion 7 in this embodiment has no particular limitation. Therefore, any superconducting material can be used. In other words, the superconductor can be selected according to the area of application.

### Embodiment 5

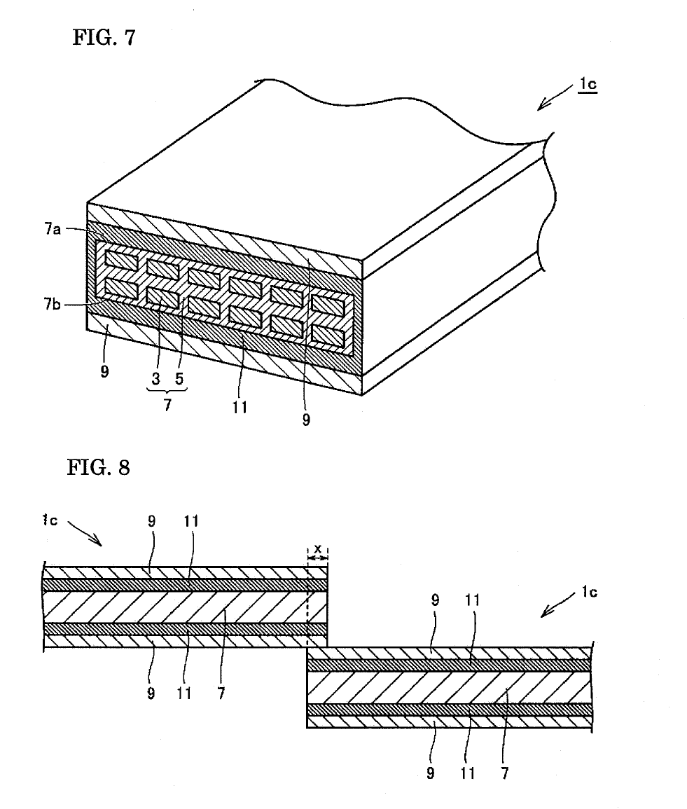

FIG. 7 is a partly cross-sectional perspective view schematically showing the structure of the superconducting tape in Embodiment 5 of the present invention. As shown in FIG. 7, a superconducting tape 1e in this embodiment has basically the same structure as that of the superconducting tape 1c in Embodiment 3, except that the main-body portion 7 is formed by using a thin-film superconducting tape. In addition, the superconducting tape 1e in this embodiment has basically the same structure as that of the superconducting tape 1d in Embodiment 4, except that the tape 1e is provided with a solder layer 11 formed so as to cover the entire circumference of the main-body portion 7 and with the reinforcement portion 9 placed on the side of the top surface 7a and on the side of the undersurface 7b of the main-body portion 7.

The method of producing the superconducting tape 1e in this embodiment is basically the same as that of producing the superconducting tape 1c in Embodiment 3, except that in the step of preparing the main-body portion 7 (Step S10), this embodiment prepares the thin-film superconducting tape. In addition, the method of producing the superconducting tape 1e in this embodiment is basically the same as that of producing the superconducting tape 1d in Embodiment 4, except that in the step of forming the solder layer 11 (Step S30), this embodiment forms the solder layer 11 such that it covers the entire circumference of the main-body portion 7 and in the step of forming the reinforcement portion 9 (Step S20), this embodiment forms the reinforcement portion 9 placed on the side of the top surface 7a and on the side of the undersurface 7b of the main-body portion 7.

According to the superconducting tape 1e and the production method thereof both in this embodiment, a thin-film superconducting tape is used as the superconductor 3 that constitutes a part of the main-body portion 7 and the reinforcement portion 9 is formed on the side of the top surface 7a and on the side of the undersurface 7b of the main-body portion 7. Even in the case where a thin-film superconducting tape is used as the main-body portion 7, by increasing the mechanical strength further, the superconducting tape 1e that can have increased allowable tension can be obtained.

### EXAMPLE

In this example, the present inventor studied the effect of providing the reinforcement portion composed of precipitation-hardened-type copper alloy or alloy of tin and copper. More specifically, in Present invention's examples 1 and 2 and Comparative examples 1 to 3, superconducting tapes were produced individually to measure the allowable tension and splice resistance of the individual superconducting tapes.

### Present Invention's Example 1

In Present invention's example 1, a superconducting tape 1c was produced in accordance with the method of producing the superconducting tape 1c in Embodiment 3 shown in FIG. 5. More specifically, in the step of preparing the main-body portion 7 (Step S10), a main-body portion 7 was prepared that had the shape of a tape and that had superconductors 3 composed of the main phase formed of a Bi2223 phase and the remainder formed of a Bi2212 phase and a nonsuperconducting phase and a sheath portion 5 made of silver. The main-body portion 7 had a thickness of 0.22 mm and a width of 4.2 mm.

Next, in the step of forming the reinforcement portion 9 (Step S20) and the step of forming the solder layer 11 (Step S30), first, two reinforcement portions 9 were prepared that were formed of precipitation-hardened-type copper alloy composed of 97% copper and 3% silver. The two reinforcement portions 9 each had a thickness of 0.02 mm and a width of 4.3 mm. They were passed through a bath holding organic-acid-based flux and a molten-solder bath in which solder composed of 99.3% Sn and 0.7% copper was melted. Subsequently, to unify the superconducting tape 1c, the main-body portion 7 and the two reinforcement portions 9 were passed through a gathering die. Thus, the reinforcement portions 9 were bonded individually to the top surface 7a and the undersurface 7b of the main-body portion 7 through the solder layer 11. The solder layer 11 had a thickness of about 3 μm.

### Present Invention's Example 2

The superconducting tape of Present invention's example 2 was different from that of Present invention's example 1 in that the reinforcement portion was composed of copper alloy in which 0.15% tin was added to the copper. In the step of forming the reinforcement portion, a copper-tin-alloy tape having a thickness of 0.02 mm and a width of 4.3 mm was used.

### Comparative Example 1

The superconducting tape of Comparative example 1 was produced by performing only the step of preparing the main-body portion (Step S10) in Present invention's example 1. Consequently, the produced superconducting tape had a thickness of 0.22 mm and a width of 4.2 mm without having the reinforcement portion 9 and the solder layer 11.

### Comparative Example 2

The superconducting tape of Comparative example 2 was different from that of Present invention's example 1 in that the reinforcement portion was composed of stainless steel and inorganic-acid-based flux was used as the flux. In the step of forming the reinforcement portion, a stainless steel tape having a thickness of 0.02 mm and a width of 4.3 mm was used.

### Comparative Example 3

The superconducting tape of Comparative example 3 was different from that of Present invention's example 1 in that the reinforcement portion was composed of brass (the class 2 brass specified in JIS C2680, which is composed of 34% copper and 66% zinc). In the step of forming the reinforcement portion, a brass tape having a thickness of 0.02 mm and a width of 4.3 mm was used.

### Measuring Method

The superconducting tapes of Present invention's examples 1 and 2 and Comparative examples 1 to 3 were subjected to the measurements of allowable tension and splice resistance. The allowable tension was measured to obtain the tension at which the critical-current value of a superconducting tape underwent the application of tension at room temperature decreases to 95% of the critical-current value of the superconducting tape before undergoing the tension application.

FIG. 8 is a cross-sectional view for explaining the method of measuring the splice resistance in Example. FIG. 8 shows the condition for measuring the splice resistance of the superconducting tape 1c of Present invention's example 1. As shown in FIG. 8, for the individual specimens of Present invention's examples 1 and 2 and Comparative examples 1 to 3, edge portions of two superconducting tapes were overlapped such that the lap “x” became 50 mm. Then, the splicing operation was performed. Under this condition, the splice resistance was measured at 77 K to obtain the resistance value. Measured results are shown in Table I.

TABLE I

| | | Splice |
|---|---|---|
| | Allowable tension (N) | resistance (nΩ) |
| Present invention's example 1 | 300 | 25 |
| Present invention's example 2 | 260 | 29 |
| Comparative example 1 | 104 | 20 |
| Comparative example 2 | 380 | 160 |
| Comparative example 3 | 210 | 40 |

### Measured Result

As shown in Table I, the superconducting tapes of Present invention's examples 1 and 2 have an allowable tension not only higher than that of Comparative examples 1 and 3 but also high enough to be next to that of Comparative example 2. The superconducting tapes of Present invention's examples 1 and 2 have a splice resistance not only much lower than that of Comparative example 2 but also comparable to that of Comparative example 1.

As described above, the examples have confirmed that the providing of a reinforcement portion composed of precipitation-hardened-type copper alloy or alloy of tin and copper enables the maintaining of high allowable tension and low splice resistance. In addition, because the reinforcement portions of Present invention's examples 1 and 2 have the same thickness as that of the reinforcement portion of Comparative example 2, it has been confirmed that even when a superconducting tape is provided with the reinforcement portion 9, the critical-current density per cross-sectional area can be suppressed from decreasing.

It is to be considered that the above-disclosed embodiments and examples are illustrative and not restrictive in all respects. The scope of the present invention is shown by the scope of the appended claims, not by the above-described embodiments. Accordingly, the present invention is intended to cover all revisions and modifications included within the meaning and scope equivalent to the scope of the claims.

### INDUSTRIAL APPLICABILITY

The superconducting tape of the present invention is particularly suitable for the technique concerning a superconducting tape having a bismuth-based superconducting material.

1. A superconducting tape, comprising:
(a) a main-body portion that has the shape of a tape and that has a superconductor; and
(b) a reinforcement portion that is composed of precipitation-hardened-type copper alloy or alloy of tin and copper and that is formed on at least one surface side of the main-body portion.

2. The superconducting tape as defined by claim 1, wherein the precipitation-hardened-type copper alloy is composed of alloy of copper and at least one material selected from the group consisting of silver, chromium, and zirconium.

3. The superconducting tape as defined by claim 1, the superconducting tape further comprising a solder layer formed between the main-body portion and the reinforcement portion.

4. A method of producing a superconducting tape, the method comprising the steps of:
(a) preparing a main-body portion that has the shape of a tape and that has a superconductor; and
(b) forming a reinforcement portion that is composed of precipitation-hardened-type copper alloy or alloy of tin and copper and that is positioned on at least one surface side of the main-body portion.

5. The method of producing a superconducting tape as defined by claim 4, wherein the step of forming a reinforcement portion includes a step of preparing the reinforcement portion composed of the precipitation-hardened-type copper alloy that is composed of alloy of copper and at least one material selected from the group consisting of silver, chromium, and zirconium.

6. The method of producing a superconducting tape as defined by claim 4, the method further comprising a step of forming a solder layer between the main-body portion and the reinforcement portion.
